(19) United States
(12) Patent Application Publication
(10) Pub. No.: US 2025/0089410 A1
(43) Pub. Date: Mar. 13, 2025

(54) PHOSPHOR-CONVERTED LIGHT EMITTING DEVICE

(71) Applicant: LUMILEDS LLC, San Jose, CA (US)

(72) Inventors: Gregoire Francois Florent DENIS, San Jose, CA (US); Rohit MODI, Hayward, CA (US)

(73) Assignee: LUMILEDS LLC, San Jose, CA (US)

(21) Appl. No.: 18/960,697

(22) Filed: Nov. 26, 2024

Related U.S. Application Data
(63) Continuation of application No. PCT/US2023/026147, filed on Jun. 23, 2023.
(60) Provisional application No. 63/356,819, filed on Jun. 29, 2022.

(51) Int. Cl. H01L 33/50

(52) U.S. Cl. CPC H10H 20/8514

(57) ABSTRACT

A phosphor layer is attached to an LED with increased precision. In particular, a phosphor ceramic is attached to an LED with glue. During the attachment process, the glue must be hardened and/or cured. The phosphor ceramic includes a hood that contains the glue in the hood as it hardens and/or is cured in order that the phosphor ceramic is properly aligned on the LED. The hood also improves the light extraction by capturing the light emitted from the sides of the LED.

### CROSS REFERENCE TO RELATED APPLICATIONS

This application is a continuation of PCT Application PCT/US2023/026147 filed Jun. 23, 2023, which claims benefit of priority to U.S. Provisional Patent Application No. 63/356,819 filed on Jun. 29, 2022. Both of the above applications are incorporated by reference in this application in their entirety.

### FIELD OF THE INVENTION

The disclosure relates generally to LEDs, pcLEDs, LED and pcLED arrays, light sources comprising LEDs, pcLEDs, LED arrays, or pcLED arrays, and displays comprising LED or pcLED arrays. Particularly, this disclosure relates to methods and devices of integrating a phosphor to a semiconductor light emitting diode.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Technological and business applications of LEDs and pcLEDs include use in displays, matrices and light engines including automotive adaptive headlights, augmented-reality (AR) displays, virtual-reality (VR) displays, mixed-reality (MR) displays, smart glasses and displays for mobile phones, smart watches, monitors and TVs, and flash illumination for cameras in mobile phones. For example, backlights for liquid crystal-displays typically employ pcLEDs comprising a combination of green and red phosphors. The individual LEDs or pcLEDs in these architectures can have an area of a few square millimeters down to a few square micrometers (microLEDs).

A particular type of wavelength converting materials is phosphor ceramics. Phosphor ceramics are widely used in the LED industry for their high quantum efficiency light conversion and exceptional thermal properties. The most common way to attach a phosphor ceramic to an LED is with glue. However, because of the unpredictable tension forces in the glue during the glue softening process, the placement of the phosphor ceramic on the LED die may be imprecise. From the standpoint of properly centering the phosphor ceramic over the LED die this is undesirable. Furthermore, the imprecise gluing process means the structure of the phosphor ceramic is limited to ceramic that is not offset from the die, which limits the types of devices that can be formed. Lastly, light may escape from the sides of the LED die, which can lead to light loss and decrease overall efficiency of the devices as a whole.

### SUMMARY

Embodiments of this invention include methods and devices of attaching a phosphor to an LED with increased precision, particularly with a hood in a phosphor ceramic that contains glue in the attachment process so that as the glue hardens and/or is cured it is properly aligned on the LED. The hood may also at least partially cover the sides of the LED, decreasing light loss so that efficiency of the light emitting device is increased.

Embodiments of this invention may be implemented in any application for general illumination, particularly any application with high temperature and high powered LEDs. Specifically, embodiments of this invention are suitable for use in automotive headlights.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display (e.g., AR/VR/MR) system.

FIG. 7 shows a cross-sectional view of an LED with a phosphor ceramic having a hood containing a glue structure.

FIG. 8 shows a cross-sectional view of an LED with a phosphor ceramic having a hood at least partially containing a glue structure extending down the side walls of the LED.

FIG. 9 shows a cross-sectional view of an LED with a phosphor ceramic having a hood containing a glue structure extending entirely down the side walls of the LED.

FIG. 10 shows a cross-sectional view of an LED with an offset phosphor ceramic having a hood containing a glue structure.

FIG. 11 shows a cross-sectional view of an array of LEDs with phosphor ceramics each having a hood containing a glue structure.

FIG. 12 shows a cross-sectional view of an array of LEDs with a continuous phosphor ceramic having hoods containing glue structures.

FIG. 13 shows a plan view of an LED with a phosphor ceramic having a hood containing a glue structure.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

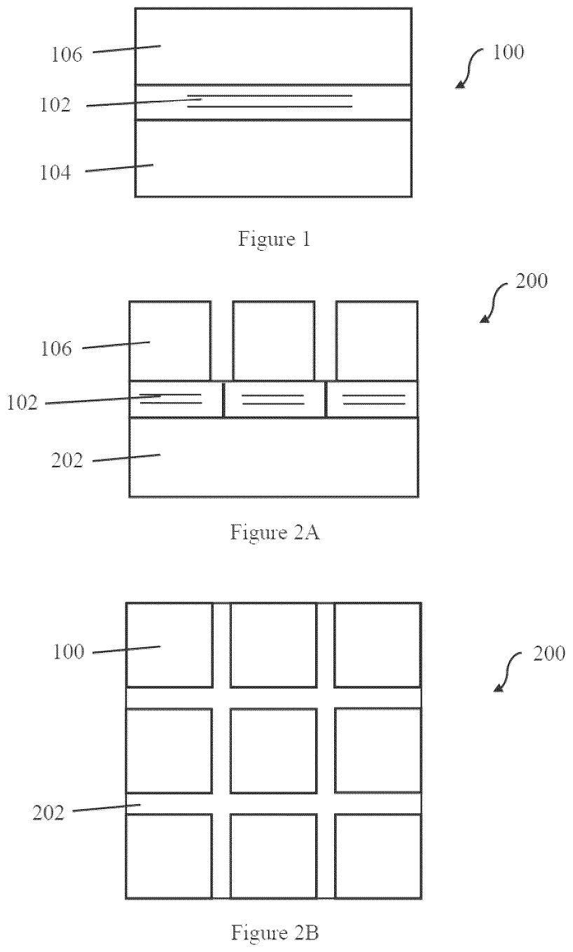

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications for the pcLED. Phosphor layers may for example comprise phosphor particles dispersed in or bound to each other with a binder material, or be or comprise a sintered ceramic phosphor plate.

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from individual mechanically separate pcLEDs arranged on a substrate. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns.

LEDs having dimensions in the plane of the array (e.g., side lengths) of less than or equal to about 50 microns are typically referred to as microLEDs, and an array of such microLEDs may be referred to as a microLED array.

Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated from each other by trenches and/or insulating material, but the electrically isolated segments remain physically connected to each other by portions of the semiconductor structure.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

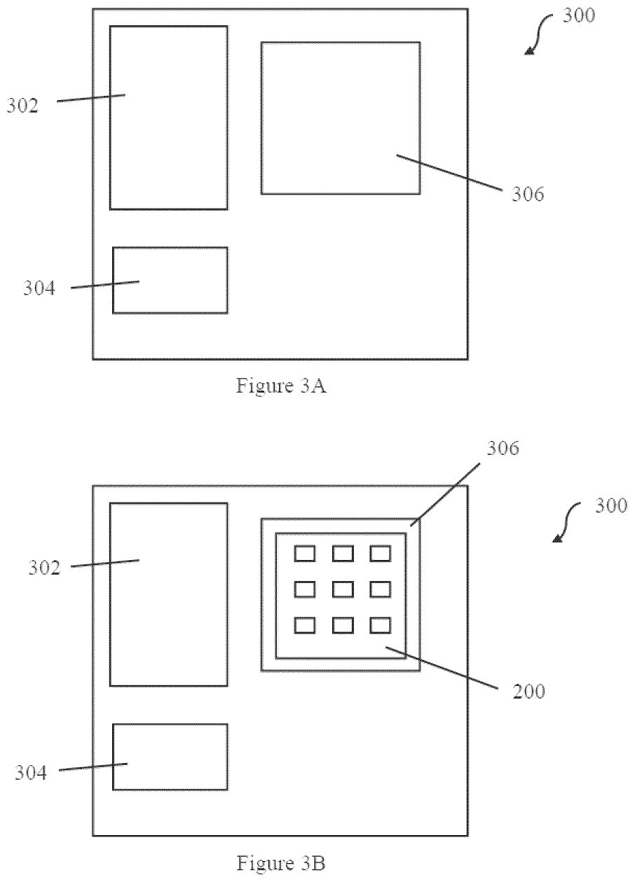

As shown in FIGS. 3A-3B, an LED or pcLED array 200 may be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

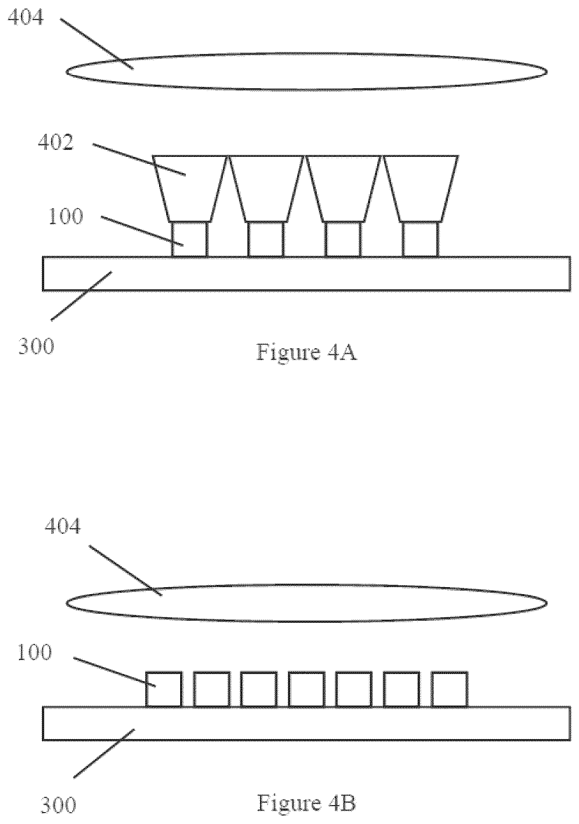

Individual LEDs or pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distribution. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), VR, and AR applications such as those described below.

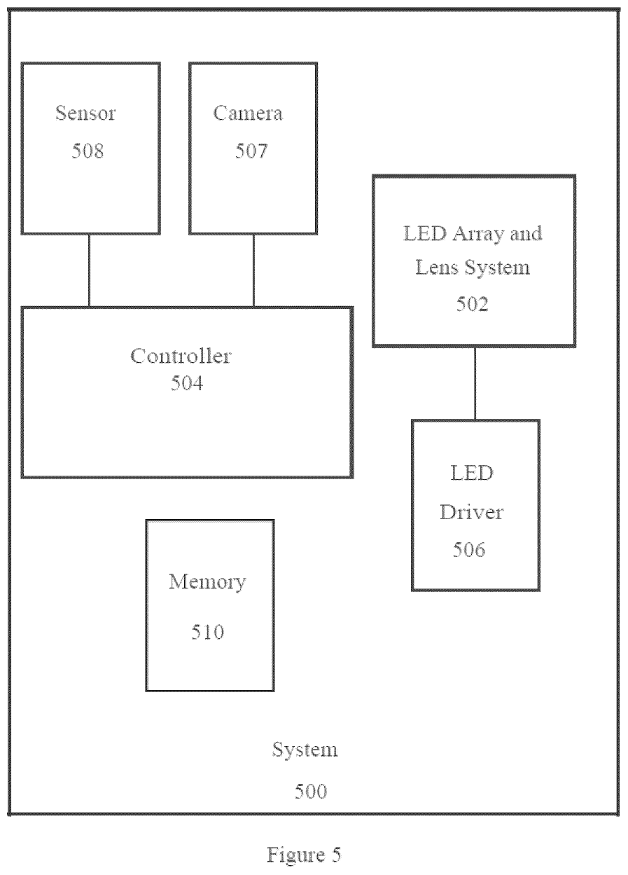

FIG. 5 schematically illustrates an example camera flash system 500 comprising an LED or pcLED array and lens system 502, which may be or comprise an adaptive lighting system as described above in which LEDs or pcLEDs in the array may be individually operable. In operation of the camera flash system, illumination from some or all of the LEDs or pcLEDs in array and lens system 502 may be adjusted—deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

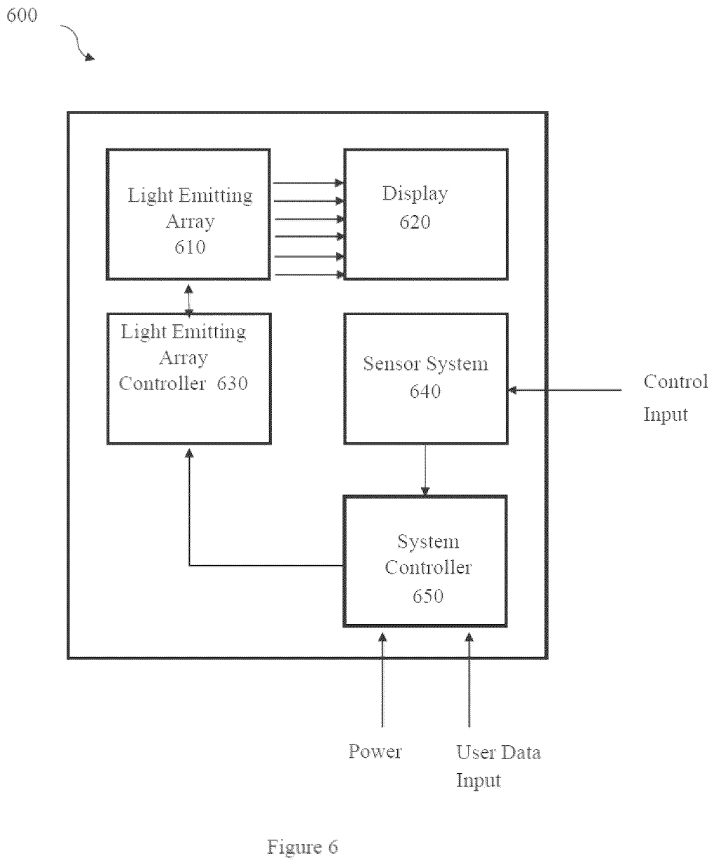

FIG. 6 schematically illustrates an example display (e.g., AR/VR/MR) system 600 that includes an array 610 of individually operable LEDs or pcLEDs, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Array 610 can be used to project light in graphical or object patterns that can support AR/VR/MR systems

Control input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

Devices as described above may include reflective or absorptive side coatings on the light emitting elements. The side coats optically isolate adjacent light emitting elements, thereby reducing cross-talk and increasing contrast between adjacent light emitting elements.

The phosphor layers used in the devices described above may be phosphor ceramics. Phosphor ceramics are particularly suited for high temperature and high powered LEDs due to their resilience, which allows them to withstand use with certain LEDs without optically degrading like other phosphor materials might.

In general, ceramic phosphors are attached to a die by a glue layer. The placement accuracy of the ceramic over the die is set by the tension forces created by the glue softening during the cure process. The placement accuracy therefore relies exclusively on self-alignment, which makes it an imprecise process, dependent upon many factors such as glue viscosity, amount of glue dispensed, etc. Furthermore, because of the self-alignment forces, the ceramic cannot be offset vis-à-vis of the die—a configuration that could be useful for specific applications. When placed on an LED die the phosphor covers only the top of the LED, leaving a large surface where the light can escape and be lost and reducing the LED efficiency.

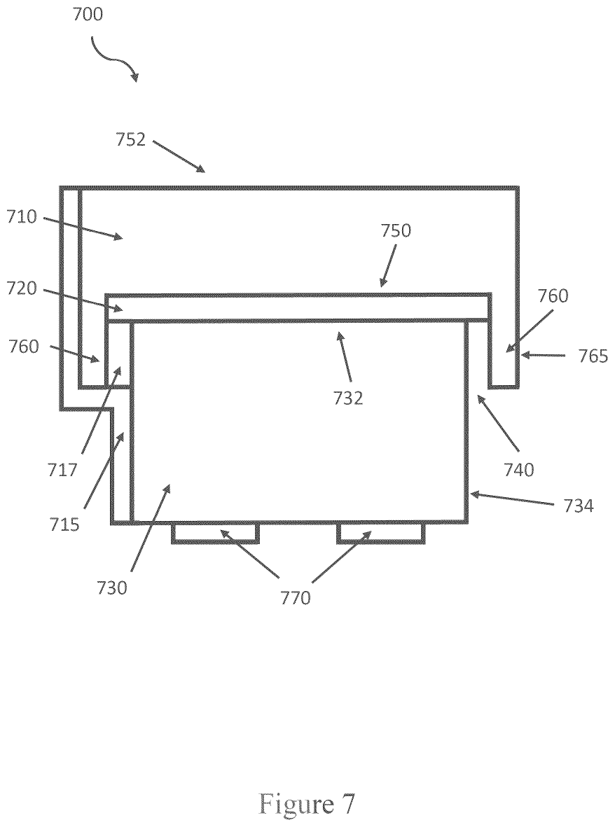

FIG. 7 shows a light emitting device 700. The light emitting device 700 includes a phosphor structure 710 with a hood 740, a glue structure 720, and an LED 730. The LED 730 may be a chip-scale package (CSP), and may be attached to contacts 770. The phosphor structure 710 may be a phosphor ceramic structure. The phosphor ceramic structure may be manufactured by various processes such as sintering or hot pressing phosphor powders together into the phosphor ceramic structure. The phosphor structure 710 is attached to the LED 730 by a glue structure 720. The phosphor structure 710 has a hood 740 in which the glue structure 720 is disposed. The hood 740 may have a primary attachment surface 750 facing a LED top light emitting surface 732, and hood side walls 760 extending out from the primary attachment surface 750, for example extending in a direction perpendicular to a plane of the primary attachment surface 750. The plane of the primary attachment surface 750 may run parallel to the LED top light emitting surface 732. The primary attachment surface 750 may have a larger area, a larger length, and/or larger width (perpendicular to the length) than the area, length, and/or width of the top light emitting surface 732 of the LED 730. As a result, the phosphor structure 710 extends to overhang the LED side walls 734 of the LED 730. The hood side walls 760 of the hood 740 extend to vertically cover the LED side walls 734. A portion of the LED side wall 734 is vertically covered when a path starting from a LED side wall 734, and extending away from the LED 730 along a horizontal direction parallel to the plane of the primary attachment surface 750, intersects a hood side wall 760. The hood side wall 760 of the hood may vertically cover at least a part of the LED side wall 734 while being spaced apart from the LED side wall 734, without directly contacting it. Alternatively, at least one of the hood side walls 760 may directly contact an LED side wall 734. Since the hood side walls 760 may at least partially vertically cover the LED side walls 734, light travelling out from the LED—e.g., from the LED side walls 734—may travel into the hood side walls 760 instead of into a reflective or absorptive side coating that may lead to light loss. In this way, the hood increases light efficiency of the light emitting device. The hood side walls 760 may not cover the entire vertical height of the LED side walls 734. For example, the hood side walls 760 may cover less than a majority of the height of the LED side walls 734, for example less than a third of the height of LED side walls 734, for example less than a quarter of the height of the LED side walls 734.

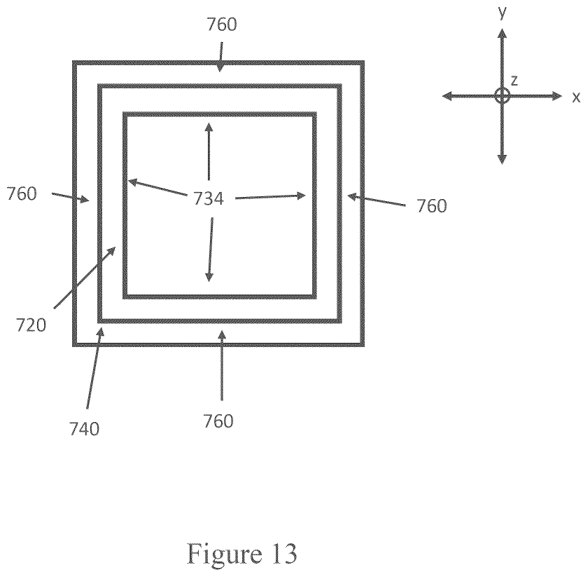

FIG. 7 shows a cross section of the light emitting device 700 where the hood side walls 760 surround the glue layer and part of the LED. FIG. 13 shows a plan view, viewing the light emitting device 700 from the vertical direction in FIG. 7 perpendicular to the plane of the LED top light emitting surface 730. FIG. 13 shows that the LED 730 may be completely surrounded on all sides (e.g., on all four sides) by hood side walls 760. In other words, each of the four LED side walls 734 are at least partially covered by one of the hood side walls 760 in the sense described above with reference to FIG. 7 (“vertically covered” in FIG. 7). The glue structure 720 may likewise be entirely surrounded on four sides by hood side walls 760. The hood 740 thus serves a purpose of containing the glue used to form the glue structure 720 so that it does not travel outside the hood 740 while the glue is setting or being cured. This increases the precision of alignment between the phosphor structure 710 and the LED 730 by the mechanical constraint of the hood. As FIG. 13 shows, the hood 740 provides a boundary for the glue to properly center the phosphor ceramic over the LED in the x-y plane and constrain rotation of the phosphor ceramic around the z-axis perpendicular to the x-y plane.

A reflective or absorptive side coating 715 may be disposed on the phosphor side surfaces 765 and the LED side walls 734. In FIG. 7 only the side coating 715 on one side is shown for case of illustration, and every side of the LED 730 and the phosphor structure 710 may be covered by the side coating 715 so that it surrounds the light emitting device 700. The side coating 715 may be in direct contact and/or conforming to the phosphor side surfaces 765 and the LED side walls 734. The reflective or absorptive side coating 715 may prevent cross-talk between light emitting devices 700 disposed next to each other, and/or reflect light which would have otherwise escaped the LED devices back into the device to prevent light loss. The side coating 715 may be a thin-film Distributed Bragg Reflector, scattering particles in a binder that function as a volume scatterer (such as TiO₂ particles), or other like coatings. In FIG. 7 the side coating 715 is illustrated to leave an air gap 717 between the hood side walls 760 and the LED side walls 734. Alternatively, the side coating 715 may fill the air gap 717 remaining in the hood 740 so that there is no air gap 717, and/or the entire LED side wall 734 is covered by the side coating 715.

The hood 740 can be referred to as a cavity in the phosphor structure. The hood may be formed by a number of techniques. For example, the hood may be formed by 1) pressing the ceramic phosphor body into a mold with the cavity shape, 2) embossing or scraping the cavity shape in the flat body of the ceramic phosphor before its sintering, 3) etching the sintered-ceramic phosphor at the cavity location, or 4) using laser ablation to create the cavity in the sintered-ceramic phosphor structure.

The primary attachment surface 750 of the hood 730 may be flat and may be designed to as closely match the area of the LED top light emitting surface 732 as possible, such that they have the same area or substantially the same area. Even so, due to tolerances, the primary attachment surface 750 may be greater than an area of the LED top light emitting surface 832, for example about 10-20 microns bigger. The phosphor structure 710 may have a phosphor light emitting surface 752 opposite to the primary attachment surface 750 of the hood 730 which is larger in length and/or width by the horizontal thicknesses of respective side walls 760. That is, the phosphor light emitting surface 752 has a greater area than the primary attachment surface 750. The heights of side walls 760 taken in the vertical direction in FIG. 7, are chosen to have enough mechanical integrity based on the height of the side walls 760 in the horizontal direction. A side wall 760 that has greater height may require a greater thickness compared to a side wall 760 of a lesser height in order to have enough mechanical integrity. The hood side walls 760 may have a horizontal thickness, for example, of from 0.5-5 microns. The hood side walls 760 may have a vertical height from, for example, 20-120 microns. The phosphor structure 710 itself may have a vertical height of from 20-200 microns, for example from 40-150 microns.

In embodiments of the invention, the glue structure 720 is disposed entirely in the hood 740. The glue structure 720 is in direct contact with the primary attachment surface 750, and may be in direct contact with at least one of the side walls 760. Alternatively, the glue structure 720 is only in direct contact with the primary attachment surface 750, without being in direct contact with any of the hood side walls 760. In any case, the glue structure 720 here is disposed entirely in the hood 740 in the sense that it is both bounded on all sides by the side walls 760, and does not extend past a vertical height of any of the side walls 760 taken in a direction perpendicular to the plane of the primary attachment surface 750. The vertical thickness of the glue structure 720 between the LED top light emitting surface 732 and the primary attachment surface 750 may be from 1-5 microns, such as from 2-3 microns.

The glue structure 720 may be a polysiloxane material that has been cured or epoxy. A

process of attaching the phosphor structure with the hood to the LED may comprise placing an amount of glue on the primary attachment surface 750 of the phosphor structure or on the LED top light emitting surface 752 of the LED. The glue may be placed on the surface as a line of glue, a droplet, or any other shape or volume. If the glue is placed on the primary attachment surface 750 of the phosphor structure, then the phosphor structure may be oriented upside down so that the phosphor light emitting surface 752 of the phosphor structure is resting on a surface. Then the LED is brought to into contact with the glue to spread it across the LED top light emitting surface 752 and the hood. If the glue is placed on the LED top light emitting surface 752, then the hood of the phosphor is brought into contact with the glue to spread it across the LED top light emitting surface 752 and the hood. Subsequently, the spread glue is cured or otherwise hardened to form the glue structure 720.

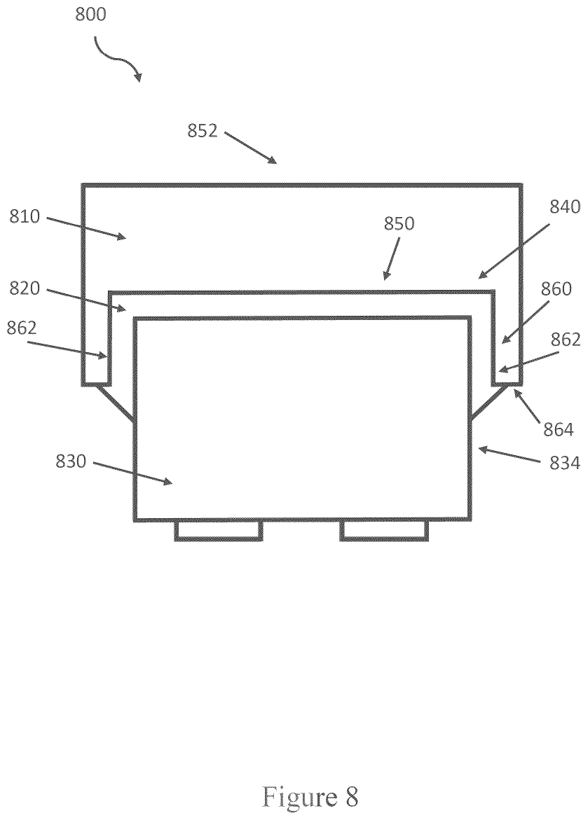

FIG. 8 shows embodiments of the invention in the form of a light emitting device 800, with a phosphor structure 810, a glue structure 820, and an LED 830. In the vertical direction, a portion of the glue structure 820 farthest from the primary attachment surface 850 extends past the hood side walls 860 to partially vertically cover the LED side walls 734. FIG. 8 shows that the glue structure 820 vertically covers the LED side walls 834 to a greater extent than the hood side walls 860. Alternatively, the glue structure 820 may vertically cover the LED side walls 734 to a lesser extent than the hood side walls 860. In any case, at least a majority of the glue structure 820 is disposed entirely in the hood. However, part of the glue structure 820 is disposed outside the hood, that is, vertically past the hood side wall 860. Some of this part of the glue structure 820 may also be disposed horizontally past the area of the primary attachment surface 850. As a result, part of the bottom surface 864 of the hood side walls 860 may be in direct contact with the glue structure 820. The bottom surface 864 of the hood side walls 860 may be perpendicular to the inner side surfaces 862 of the hood side walls 864, and parallel to the primary attachment surface 850 of the hood. The area of the bottom surfaces 864 added with the area of the primary attachment surface 850 may be equal to or substantially equal to an area of the phosphor light emitting surface 852.

When the glue structure 820 vertically extends past the hood side walls 860, the entire inner side surface 862 of the hood side walls 860 are directly in contact with the glue structure 820. As a result, the entire volume of the hood is filled with (at least portions of) the glue structure 820 and the LED 830.

The glue structure 820 extending to vertically cover the LED side walls 834 may help light extraction, particularly with the wings extending outside of the hood to cover additional parts of the LED. When light is emitted through the LED side walls 834, it might travel into a reflective or absorptive side coating which may cause light loss. If instead it travels into the glue structure 820, it may be guided to the phosphor ceramic without suffering as much light loss. In this way the light efficiency of the device is increased.

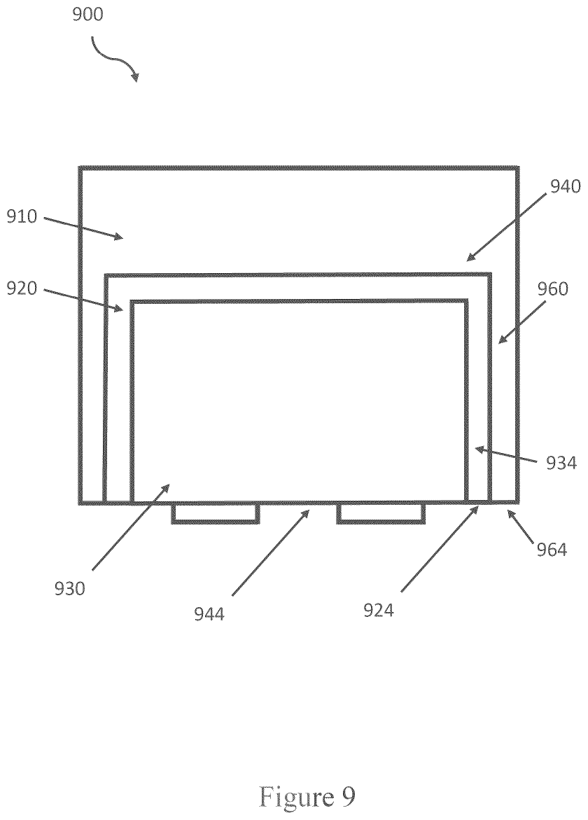

FIG. 9 shows embodiments of the invention in the form of a light emitting device 900, with a phosphor structure 910, a glue structure 920, and an LED 930. In the vertical direction, the glue structure 920 may extend to fully vertically cover or substantially fully vertically cover the LED side walls 934. The hood side walls 960 may also extend to fully vertically cover or substantially fully vertically cover the LED side walls 934. Consequently, the hood side walls 960 may fully vertically cover or substantially fully vertically cover the glue structure 920. The hood 940 may fully contain or substantially fully contain the entirety of the LED 930 and the glue structure 920. That is, no part or substantially no part of the LED 930 and the glue structure 920 may vertically extend past the bottom surface 964. In other words, the glue bottom surface 924 and the LED bottom surface 944 may be flush or substantially flush with both each other and the bottom surface 964 of the hood side walls 960. The bottom surface 964 of the hood side walls 960 may be adjacent to but not directly in contact with any part of the glue structure 920.

A vertical height of the hood side walls 960 may be equal to a vertical height of the glue structure 920. A vertical height of the glue structure 920 may be greater than a vertical height of the LED 930. The glue structure 920 may completely horizontally surround the LED 930, and the hood side walls 960 may completely horizontally surround both the LED 930 and the glue structure 920.

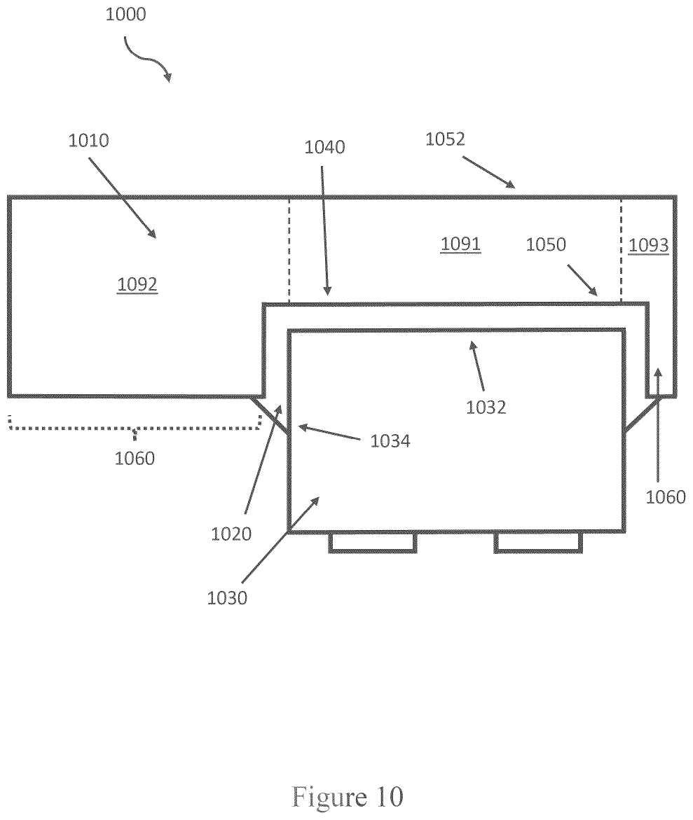

FIG. 10 shows embodiments of the invention in the form of a light emitting device 1000, with a phosphor structure 1010, a glue structure 1020, and an LED 1030. Phosphor structure 1010 has an offset structure over the LED 1030. That is, phosphor structure 1010 is asymmetrically disposed above the LED 1030. An offset phosphor ceramic may produce an asymmetric emission profile, with more light on one side of the device, which can simplify primary and secondary optics used in conjunction with the light emitting device as they may not have to bend light as much to give the final beam its desired shape. The phosphor structure 1010 can be conceptually partitioned: a first portion 1091 of the phosphor structure 1010 is disposed directly over the LED top light emitting surface 1032, a second portion 1092 of the phosphor structure 1010 is disposed adjacent to the leftmost of the LED side walls 1034 (left side of the page in FIG. 10) and third portion 1093 of the phosphor structure 1010 is disposed adjacent to the rightmost of the LED side walls 1034 (right side of the page in FIG. 10). FIG. 10 shows these portions divided by imaginary dashed lines. The second portion 1092 of the phosphor structure 1010 comprises more of the phosphor structure 1010 (e.g., more volume) than the third portion 1093 of the phosphor structure 1010. The second portion 1092 may have the same (maximum) vertical thickness as the third portion 1093, but may have a greater area of the phosphor light emitting surface 1052 than the area of the phosphor light emitting surface 1052 in the third portion 1091. The second portion 1092 may have a same, lesser, or greater volume of phosphor structure 1010 as the first portion 1091. The third portion 1093 may have a lesser volume of phosphor structure 1010 compared to the first portion 1091. The second portion 1092 and the third portion 1093 may each comprise respective hood side walls 1060.

Another way of characterizing the offset structure of the phosphor structure 1010 is that the phosphor structure 1010 has an asymmetric shape and volume with respect to a vertical and/or horizontal line running through a center of the primary attachment surface 1050 and/or a center of the LED top light emitting surface 1032. Furthermore, the hood side wall 1060 on one side of the hood (left side of FIG. 10) has a greater vertical thickness than a hood side wall 1060 on the other side of the hood (right side of FIG. 10).

If the phosphor structure 1010 were attached to the LED 1030 with glue that was then cured or otherwise solidified into glue structure 1020, without having the hood 1040, then the offset of the phosphor structure 1010 over the LED 1030 may cause misalignment of the phosphor structure 1010, particularly since the offset provides additional area for the alignment of the hardening glue to stray over a phosphor structure without an offset. On the other hand, with the hood 1040, the self-alignment of the hardening glue can be restricted to the hood area, allowing the offset structure of the phosphor structure 1010 to be properly attached to the LED 1030.

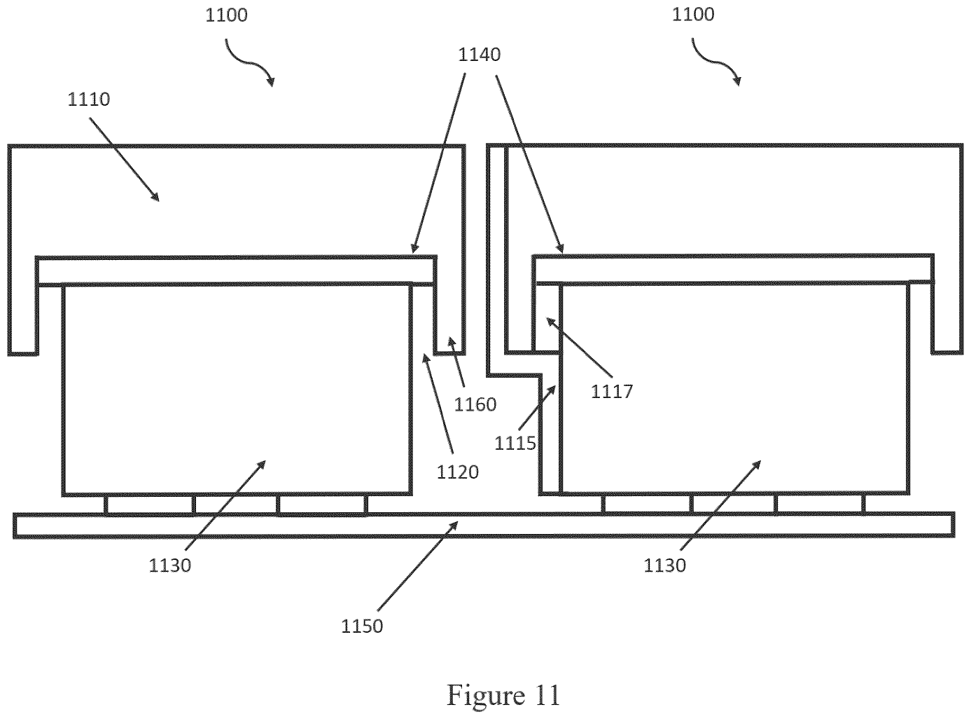

FIG. 11 shows embodiments of the invention in the form of an array of light emitting devices 1100 on a substrate 1150, with phosphor structures 1110, glue structures 1120, and LEDs 1130. The hoods 1140 reduce the gap between the light emitting devices 1100, which are placed adjacent to each other. A small gap is wished to reduce dark zones in the emitting array. However, small gap generally increases crosstalk of the pixels in the array. The hoods 1140 allow for placing the devices as close to each other, yet reducing the crosstalk between the LEDs and the phosphors. This is particularly true when the light emitting devices 1100 are covered by reflective or absorptive side coats 1115. In FIG. 11 only one side coating 1115 is shown for clarity, but like described with relation to the side coating in FIG. 7, the side coating 1115 may cover any or all sides of each of the light emitting devices 1100.

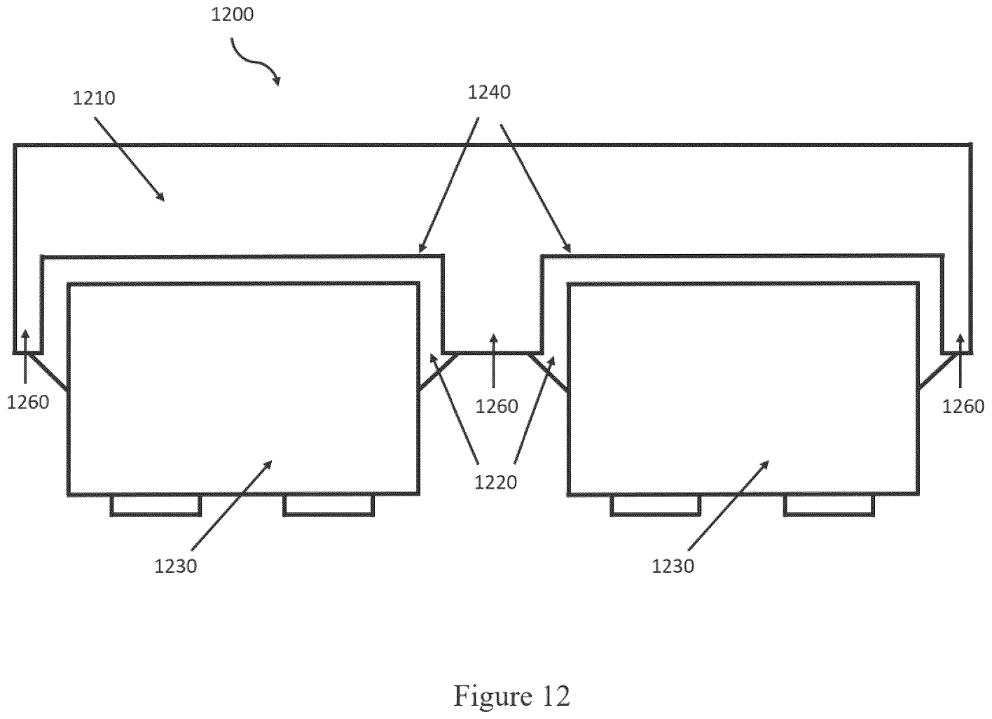

FIG. 12 shows embodiments of the invention in the form of an array 1200 of light emitting devices, with a phosphor structure 1210, glue structures 1220, and LEDs 1230. The phosphor structure 1210 is disposed over multiple LEDs 1230, and may be a continuous, unitary structure over the entire space over and between LEDs. The phosphor structure 1210 has multiple hoods 1240 designed to correspond to the positions of each LED 1230. Adjacent hoods 1240 may share a hood side wall 1260 disposed between them. The shared hood side wall 1260 may be horizontally thicker than the hood side walls 1260 that are not shared, e.g., the hood side walls 1260 on the outer part of the array 1200 which are not between at least two LEDs 1230 and/or are adjacent to only one LED 1230. Alternatively, the shared hood side walls 1260 may be a same horizontal thickness as hood side walls 1260 that are not shared. The individual, separated glue structures 1220 may be partially or entirely contained in their respective hoods 1240. Even when the glue structures 1220 are only partially contained in their respective hoods 1240, they may not be in direct contact with each other and may only directly contact a respective one of the LEDs 1230 without contacting the others.

Although FIG. 12 illustrates the phosphor structure 1210 disposed over two LEDs 1230 arranged along one dimension (e.g., along a horizontal line), the phosphor structure 1210 may be disposed over more LEDs 1230 arranged two dimensions, such as a 3×3, 7×7, or 9×9 array of LEDs arranged in a rectangular grid, such that the phosphor structure 1210 has a 3×3, 7×7, or 9×9 array of hoods arranged in a rectangular grid to be disposed over the LEDs.

The multiple hoods in the phosphor structure allow attaching of multiple LEDs with a single phosphor ceramic structure using glue, preventing tilting of the phosphor structure over the array and other possible misalignment (for example caused by height differences in the LEDs), particularly when the glue is softening.

This disclosure is illustrative and not limiting. Further modifications will be apparent to one skilled in the art in light of this disclosure and are intended to fall within the scope of the appended claims. For example, in the descriptions of specific embodiments above, elements may share same or similar characteristics as other embodiments described in this specification though not explicitly stated.

1. A wavelength converting structure, comprising:
a phosphor ceramic structure comprising:
a top surface that is planar, a plane of the top surface comprising a horizontal direction perpendicular to a vertical direction,
a hood opposite the top surface and comprising:
an attachment surface parallel to and having a smaller area than the top surface, the attachment surface being planar and configured to attach to a light emitting die via a glue layer, and
hood side walls extending in the vertical direction away from the attachment surface and the top surface and completely horizontally surrounding the attachment surface, the hood side walls each having a horizontal thickness that is lesser than a vertical height of the phosphor ceramic structure,
phosphor side surfaces extending perpendicularly in the vertical direction away from the top surface to a bottom of the hood side walls that is opposite the top surface, the phosphor side surfaces being planar and comprising a top region adjacent to the top surface and a bottom region below the top region that is a part of the hood side walls.

2. The wavelength converting structure of claim 1, wherein the attachment surface has a rectangular area.

3. The wavelength converting structure of claim 2, wherein the attachment surface has a square area.

4. The wavelength converting structure of claim 2, wherein the hood side walls consists of four hood side walls.

5. The wavelength converting structure of claim 1, wherein the phosphor ceramic structure has an asymmetric shape with respect to an imaginary line running through a center of the hood.

6. The wavelength converting structure of claim 5, wherein one of the hood side walls has a greater horizontal thickness than another one of the hood side walls.

7. The wavelength converting structure of claim 1, wherein the hood is a first hood, and the phosphor ceramic structure further comprises a second hood adjacent to the first hood, the second hood comprising:
a second attachment surface opposite to, parallel to, and having a smaller area than the top surface, the attachment surface being planar and configured to attach to a second light emitting die via a second glue layer, and
second hood side walls extending in the vertical direction away from the second attachment surface and the top surface and completely horizontally surrounding the second attachment surface, the second hood side walls comprising the bottom region of the phosphor side surfaces.

8. The wavelength converting structure of claim 1, wherein the hood side walls and the second hood side walls both comprise a shared side wall, the shared side wall having a different vertical thickness relative to another one of the hood side walls and another one of the second hood side walls.

9. A light emitting device, comprising:
an LED with an LED light emitting surface comprising a horizontal direction perpendicular to a vertical direction, and LED side surfaces extending away from the LED light emitting surface in the vertical direction;
a phosphor ceramic structure disposed on the LED and comprising:
a top surface;
a hood opposite the top surface, the hood comprising:
an attachment surface, and
hood side walls extending away from the attachment surface and the top surface and at least partially vertically covering the LED side surfaces, the hood side walls each having a horizontal thickness that is lesser than a height of the phosphor ceramic structure, and
phosphor side surfaces extending away from the top surface to a bottom of the hood side walls that is opposite the top surface, such that a region of the phosphor side surfaces is a part of the hood side walls, and
a glue structure between and bonding the LED and the phosphor ceramic structure.

10. The light emitting device of claim 9, wherein the glue structure is entirely contained in the hood.

11. The light emitting device of claim 9, wherein the glue structure vertically extends beyond the hood side walls.

12. The light emitting device of claim 9, wherein the hood side walls entirely vertically cover the LED side surfaces.

13. The light emitting device of claim 12, wherein the glue structure entirely vertically cover the LED side surfaces.

14. The light emitting device of claim 9, wherein the hood side walls entirely horizontally surround the LED.

15. The light emitting device of claim 10, wherein the phosphor ceramic structure has an asymmetric volume with respect to an imaginary center line running through a center of the LED light emitting structure.

16. The light emitting device of claim 9, wherein the hood side walls do not entirely vertically cover the LED side surfaces.

17. An array comprising multiple of the light emitting device of claim 9.

18. An array of light emitting devices, comprising:
LEDs each having an LED light emitting surface comprising a horizontal direction perpendicular to a vertical direction, and LED side surfaces extending away from the LED light emitting surface in the vertical direction;
a continuous phosphor ceramic structure disposed on the LEDs and comprising:
a top surface;
hoods adjacent to each other and opposite the top surface, the hoods each comprising:
an attachment surface, and
hood side walls extending away from the attachment surface, at least one of the hood side walls each having a horizontal thickness that is lesser than a height of the continuous phosphor ceramic structure and
phosphor side surfaces extending away from the top surface to a bottom of some of the hood side walls that is opposite the top surface, such that a region of the phosphor side surfaces is a part of the some of the hood side walls, and
respective glue structures between and bonding respective ones of the LEDs to the phosphor ceramic structure.

19. The array of claim 18, wherein the respective glue structures are each contained in a respective one of the hoods and are not in direct contact with each other.

20. The array of claim 18, wherein the hood side walls comprised shared hood side walls shared between adjacent hoods, the shared hood side walls having a greater horizontal thickness than those others of the hood side walls.
